(19) United States
(12) Patent Application Publication
(10) Pub. No.: US 2017/0369982 A1
(43) Pub. Date: Dec. 28, 2017

(54) SCREEN TENSIONING DEVICE USED DURING FABRICATING MASK PLATE AND SCREEN TENSIONING METHOD

(71) Applicant: BOE TECHNOLOGY GROUP CO., LTD., Beijing (CN)

(72) Inventors: Lifei MA, Beijing (CN); Yinan LIANG, Beijing (CN)

(21) Appl. No.: 15/526,889

(22) PCT Filed: Mar. 2, 2016
(86) PCT No.: PCT/CN2016/075340

§ 371 Date: May 15, 2017

(30) Foreign Application Priority Data
May 15, 2015 (CN) 201510250442.6

(51) Int. Cl. C23C 14/04; C23C 14/24; H01L 51/56; H01L 51/00

(52) U.S. Cl. CPC C23C 14/042; H01L 51/56; C23C 14/24; H01L 51/001; H01L 51/0011

(57) ABSTRACT

A screen tensioning device used during fabrication of mask plate includes a screen tensioning machine base and a jig disposed on the screen tensioning machine base, and further includes a magnetic plate positioned above the screen tensioning machine base, and an upwardly-directed vertical suction force acting on the screen of the mask plate to be fabricated by the magnetic plate is equal to an upwardly-directed vertical suction force acting on the screen of the mask plate by a magnetic field system in a vacuum evaporation chamber during evaporation. A screen tensioning method used during fabrication of mask plate is also provided.

### TECHNICAL FIELD

Embodiments of the present disclosure relate to a screen tensioning device used during fabricating a mask plate and a screen tensioning method.

### BACKGROUND

At present, during the process of fabricating a color filter layer of an OLED (Organic Light-Emitting Diode) display screen, a mask plate having a pattern is used for masking process and a pattern as required is formed on a substrate to be evaporated by vacuum evaporation. A conventional mask plate comprises a screen and a screen frame. When the screen and the screen frame are combined, it is necessary to use a screen tensioning device to tension the screen on the screen frame. And then the screen is fastened to the screen frame, thereby forming a mask plate as required.

As shown in FIG. 1, the screen tensioning device 00 of the conventional arts mainly comprises a screen tensioning machine 21 and a jig 25 disposed on the screen tensioning machine 21. During use, a screen frame 22 and an aligned substrate 23 are placed on the screen tensioning machine 21, a screen 24 is disposed on the screen frame 22, and the aligned substrate 23 is positioned directly under the screen 24. The main steps of fabricating a mask plate by use of the screen tensioning device are as follows: placing and fixing the screen frame 22 and the aligned substrate 23 on the screen tensioning machine 21, disposing the screen 24 on the screen frame 22 and clamping edges of the screen 24 by the jig 25; tensioning the screen 24 by use of the jig 25 so that the pattern on the screen 24 is aligned with the pattern on the aligned substrate 23; and then fastening the screen 24 onto the screen frame 22, thereby forming a required mask plate.

However, when the mask plate is used for masking process, the screen 24 of the fabricated mask plate is sagged by the gravity of the screen 24 itself, which results in that it is difficult to align the pattern on the screen 24 with the region to be deposited with pattern on the substrate to be evaporated. Thus, the position accuracy of the pattern formed by evaporating the organic materials on the substrate to be evaporated would be affected.

### SUMMARY

Embodiments of the present disclosure provides a screen tensioning device used during fabrication of mask plate and a screen tensioning method used during fabrication of mask plate. When using the mask plate fabricated by the screen tensioning device, the position accuracy of the pattern formed by evaporating the organic materials onto the substrate to be evaporated is be improved.

At least one embodiment of the present disclosure provides a screen tensioning device used during fabrication of mask plate, comprising a screen tensioning machine base and a jig provided on the screen tensioning machine base, the screen tensioning device further comprising a magnetic plate positioned above the screen tensioning machine base, and an upwardly-directed vertical suction force acting on the screen of the mask plate to be fabricated by the magnetic plate is equal to an upwardly-directed vertical suction force acting on the screen of the mask plate by a magnetic field system in a vacuum evaporation chamber during masking process.

At least one embodiment of the present disclosure provides a screen tensioning method used during fabrication of mask plate, which is applicable to the screen tensioning device according to any one of claims 1 to 5, the screen tensioning method comprising:

placing and fixing the screen frame and an aligned substrate onto the screen tensioning machine base;

disposing the screen on the screen frame and positioning the screen under the magnetic plate, wherein the magnetic plate generates an upwardly-directed vertical suction force on the screen, and the upwardly-directed vertical suction force acting on the screen by the magnetic plate is equal to the upwardly-directed vertical suction force acting on the screen by a magnetic field system in a vacuum evaporation chamber during evaporation;

clamping an edge of the screen by the jig in the screen tensioning device and tensioning the screen by use of the jig so that the pattern on the screen is aligned with the pattern on the aligned substrate; and

combining the aligned screen and the screen frame so as to form a mask plate as required.

Compared with the screen tensioning device of the conventional arts, the screen tensioning device used during fabrication of mask plate and the screen tensioning method used during fabrication of mask plate according to an embodiment of the present disclosure is additionally provided with a magnetic plate, so that a magnetic field environment in the vacuum evaporation chamber can be simulated when the mask plate is fabricated. That is to say, in the present disclosure, the mask plate is fabricated in a magnetic field environment which is similar to the magnetic field environment in the vacuum evaporation chamber. In this case, the mask plate are applied with identical forces in the vertical direction in fabrication and in use, i.e., the mask plate is subjected to its own gravity which is in vertically downward direction and a suction force by the magnetic field which is in vertically upward direction, which makes the position of the pattern (referred to the pattern on the screen of the mask plate) of the mask plate in fabrication is the same position as the pattern of the mask plate in use, thereby facilitating the alignment of the pattern on the screen of the mask plate with a region of the substrate to be evaporated where a pattern needs to be deposited. Therefore, compared with the conventional arts, when using the mask plate fabricated by the screen tensioning device according to the embodiment of the present disclosure, the position accuracy of the pattern formed by evaporating the organic materials onto the substrate to be evaporated can be improved.

### BRIEF DESCRIPTION OF THE DRAWINGS

In order to clearly illustrate the technical solutions of the embodiments of the disclosure, the drawings of the embodiments will be briefly described in the following; it is obvious that the drawings described below are only related to some embodiments of the disclosure and thus are not limitative of the disclosure.

FIG. 1 is a side view of a screen tensioning device used during fabrication of mask plate in the conventional arts;

FIG. 2 is a side view of a screen tensioning device used during fabrication of mask plate according to an embodiment of the present disclosure;

FIG. 3 is an illustrative view of a screen tensioning device used during fabrication of mask plate according to an embodiment of the present disclosure; and

FIG. 4 is a flow chart of a screen tensioning method used during fabrication of mask plate according to an embodiment of the present disclosure.

### DETAILED DESCRIPTION

In order to make objects, technical details and advantages of the embodiments of the disclosure apparent, the technical solutions of the embodiment will be described in a clearly and fully understandable way in connection with the drawings related to the embodiments of the disclosure. It is obvious that the described embodiments are just a part but not all of the embodiments of the disclosure. Based on the described embodiments herein, those skilled in the art can obtain other embodiment(s), without any inventive work, which should be within the scope of the disclosure.

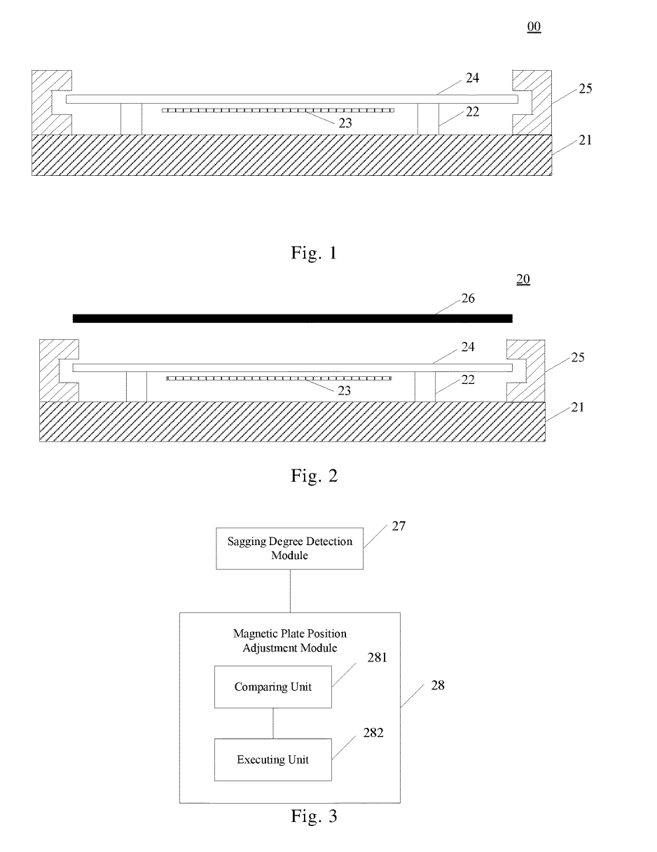

As illustrated in FIG. 2, the screen tensioning device 20 used during fabrication of mask plate according to an embodiment of the present disclosure comprises a screen tensioning machine 21, a jig 25 disposed on the screen tensioning machine 21 and a magnetic plate 26 positioned above the screen tensioning machine 21 and matching a screen 24. The screen tensioning machine 21 is configured to carry a screen frame 22 and an aligned substrate 23 (which can be an aligned glass substrate) as well as the screen 24 disposed on the screen frame 22, in addition to installing the jig 25. The jig 25 is configured to clamp the screen 24 and can tension the screen 24. For the sake of cost-saving, the screen tensioning machine 21 and the jig 25 as illustrated in FIG. 1 can be used as the screen tensioning machine base 21 and the jig 25 respectively. The magnetic plate 26 is provided to apply a vertically upward suction force on the screen plate 24. For example, the magnetic plate 26 can be a magnetic plate made of a permanent magnet material or a plate-like electromagnet.

When the mask plate is fabricated, firstly, the screen frame 22 and the aligned substrate 23 are placed and fixed onto the screen tensioning machine 21, the screen 24 is disposed on the screen frame 22 and is positioned under the magnetic plate 26 which apply a vertically upward suction force on the screen 24, wherein the vertically upward suction force acting on the screen 24 of the mask plate to be fabricated by the magnetic plate 26 is equal to a vertically upward suction force applied on the screen 24 of the mask plate by the magnetic field system in the vacuum evaporation chamber. And then, edges of the screen 24 are clamped by the jig 25 and the screen 24 is tensioned by use of the jig 25, so that the pattern on the screen 24 is aligned with the pattern on the aligned substrate 23. In practical, a CCD (Charge-coupled Device) camera can be used to determine whether the pattern of the screen 24 is aligned with the pattern of the aligned substrate 23. And then, after determining that the pattern of the screen 24 is aligned with the pattern of the aligned substrate 23, the screen 24 is combined with the screen frame 22. For example, the screen frame 22 and the screen 24 can be welded together by a laser welding apparatus so as to form a mask plate.

In can be seen from the above that compared with the screen tensioning device of the conventional arts, the screen tensioning device used during fabrication of mask plate according to an embodiment of the present disclosure is additionally provided with a magnetic plate, so that a magnetic field environment in the vacuum evaporation chamber can be simulated when the mask plate is fabricated. That is to say, in the present disclosure, the mask plate is fabricated in a magnetic field environment which is similar to the magnetic field environment in the vacuum evaporation chamber. In this case, the mask plate are applied with identical forces in the vertical direction in fabrication and in use, i.e., the mask plate is subjected to its own gravity which is in vertically downward direction and a suction force by the magnetic field which is in vertically upward direction, which makes the position of the pattern (referred to the pattern on the screen of the mask plate) of the mask plate in fabrication is the same position as the pattern of the mask plate in use, thereby facilitating the alignment of the pattern on the screen of the mask plate with a region of the substrate to be evaporated where a pattern needs to be deposited. Therefore, compared with the conventional arts, when using the mask plate fabricated by the screen tensioning device according to the embodiment of the present disclosure, the position accuracy of the pattern formed by evaporating the organic materials onto the substrate to be evaporated can be improved.

Hereinafter, the screen tensioning device used in fabrication of mask plate according to an embodiment of the present disclosure will be described in detail. Regarding components and position or connection relationships of the components of the screen tensioning device used in fabrication of mask plate according to the present embodiment, the description in the above-described embodiment can be referred to, and a description thereof is omitted here.

In FIG. 2, the aligned substrate 23 and the magnetic plate 26 can be supported by different supporting structures (not illustrated in FIG. 2) on the screen tensioning machine 21 and a supporting structure configured to support the aligned substrate 23 has a height different from that of a supporting structure configured to support the magnetic plate 26. For example, the height of the supporting structure configured to support the magnetic plate 26 is greater than that of the supporting structure configured to support the aligned substrate 23. The supporting structures can be supporting pins for example.

In the present embodiment, to make the conditions of the magnetic field environment in fabrication of the mask plate consistent with the conditions of the magnetic field environment in use of the mask plate, the vertically upward suction force applied on the screen 24 by the magnetic plate 26 is required to be equal to the vertically upward suction force applied on the screen 24 by the magnetic field system in the vacuum evaporation chamber. When the vertically upward suction force applied on the screen 24 by the magnetic plate 26 and the vertically upward suction force applied on the screen 24 by the magnetic field system in the vacuum evaporation chamber are not equal, it is necessary to adjust the suction force applied on the screen 24 by the magnetic plate 26 to achieve a required suction force. For example, the adjustment of the suction force can be achieved by moving the magnetic plate 26 in the vertical direction relative to the screen tensioning machine 21. That is to say, the suction force applied on the screen 24 by the magnetic plate 26 can be adjusted by adjusting the distance between the magnetic plate 26 and the screen 24. The suction force applied on the screen 24 by the magnetic plate 26 can be gauged on basis of sagging degree of the screen 26.

When the sagging degree of the screen 24 is relatively great, the suction force applied on the screen 24 by the magnetic plate 26 can be considered as relatively low. In this case, to reduce the sagging degree of the screen 26, it is necessary to increase the suction force applied on the screen 24 by the magnetic plate 26, i.e., it is necessary to move the magnetic plate 26 towards the screen 24. When the sagging degree of the screen 24 is relatively low, the suction force applied on the screen 24 by the magnetic plate 26 can be considered as relatively great. In this case, to increase the sagging degree of the screen 24, it is necessary to decrease the suction force applied on the screen 24 by the magnetic plate 26, i.e., it is necessary to move the magnetic plate 26 away from the screen 24.

Therefore, in one embodiment of the present disclosure, as illustrated in FIG. 3, the screen tensioning device 20 used in fabrication of mask plate can further comprise a sagging degree detection module 27 configured to detect the sagging degree of the screen 24; a magnetic plate position adjustment module 28 connected with the sagging degree detection module 27 and the screen 24, which adjusts the distance between the magnetic plate 26 and the screen tensioning machine 21 in the vertical direction according to the sagging degree of the screen 24 detected by the sagging degree detection module 27. The sagging degree detection module 27 can be a laser flatness detecting device, which judges the sagging degree of the screen 24 by emission and reflection optical paths of laser. The magnetic plate position adjustment module 28 can be a manipulator and the like.

The magnetic plate position adjustment module 28 can comprise a comparison unit 281 connected with the sagging degree detection module 27 and configured to compare the sagging degree of the screen 24 detected by the sagging degree detection module with a preset sagging degree and generate a comparison result.

The screen tensioning device 20 can further comprise an executing unit 282 connected with the comparing unit 281 and the magnetic plate 26 and configured to acquire the comparison result from the comparing unit 281 and adjust the distance between the magnetic plate 26 and the screen tensioning machine 21 in the vertical direction according to the comparison result.

The executing unit 282 can be configured to move the magnetic plate 26 towards the screen 24 when the sagging degree detected by the magnetic plate position adjustment module 28 is greater than the preset sagging degree, to move the magnetic plate 26 away from the screen 24 when the detected sagging degree is less than the preset sagging degree, and to fix the position of the magnetic plate 26 when the detected sagging degree is equal to the preset sagging degree. In the context of the present disclosure, the preset sagging degree refers to a sagging degree generated by the suction force applied on the screen 24 by the magnetic field system for absorbing the mask plate and the gravity of the screen 24 itself when the mask plate is used for performing masking in the vacuum evaporation chamber.

In can be seen from the above that when the mask plate is fabricated by the screen tensioning device used in fabrication of mask plate according to the embodiment of the present disclosure, a magnetic field environment in the vacuum evaporation chamber is simulated, so that the mask plate is applied with identical forces in the vertical direction in fabrication and in use, i.e., the mask plate is subjected to its own gravity which is in vertically downward and a magnetic field suction force which is in vertically upward, which makes the pattern (referred to the pattern on the screen of the mask plate) of the mask plate in fabrication is in the same position as the pattern of the mask plate in use. The position accuracy of the pattern formed by evaporating the organic materials onto the substrate to be evaporated can be improved.

In addition, in order that the magnetic plate 26 generates a uniform magnetic field to the screen 24, for example, the magnetic plate 26 generates a magnetic field covering the entire screen 24, in one embodiment of the present disclosure, the magnetic plate 26 is configured to have the same size as the screen 24 (it is to be noted that the “same size” here means the magnetic plate 26 and the screen 24 have the same plane area on their respective planes when the magnetic plate 26 and the screen 24 are arranged in parallel). The magnetic plate 26 can be a large magnet or can be comprised of a plurality of small magnets. When the magnetic plate 26 is comprised of a plurality of small magnets, the suction force acting on the screen 24 by the magnetic plate 26 can be also adjusted by increasing or decreasing the number of magnets, so that the sagging degree of the screen 24 can be adjusted.

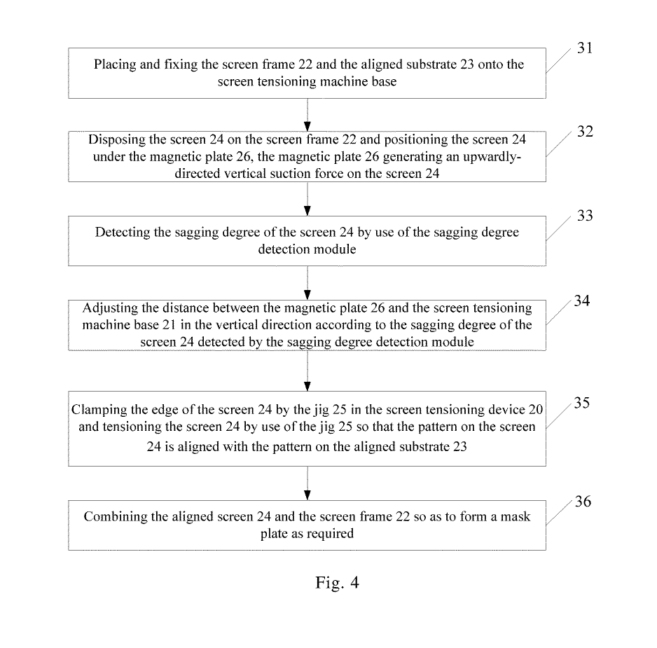

As illustrated in FIG. 4, at least one embodiment of the present disclosure provides a screen tensioning method used during fabrication of mask plate, which is applicable to the above-described screen tensioning device. The screen tensioning method comprises the following steps.

A step 31 of placing and fixing the screen frame 22 and the aligned substrate 23 onto the screen tensioning machine base.

A step 32 of disposing the screen 24 on the screen frame 22 and positioning the screen 24 under the magnetic plate 26, the magnetic plate 26 generating an upwardly-directed vertical suction force on the screen 24. To make the environmental conditions during fabrication of the mask plate and the environmental conditions during use of the mask plate as consistent as possible, the upwardly-directed vertical suction force acting on the screen 24 by the magnetic plate 26 is equal to the upwardly-directed vertical suction force acting on the screen 24 by the magnetic field system in the vacuum evaporation chamber during masking process. In one embodiment of the present disclosure, the magnetic plate 26 and the screen 24 are of the same size, so that it is easier that the upwardly-directed vertical suction force acting on the screen 24 by the magnetic plate 26 is made equal to the upwardly-directed vertical suction force acting on the screen 24 by the magnetic field system in the vacuum evaporation chamber during masking process.

To adjusting the suction force acting on the screen 24 by the magnetic plate 26, it is required that the magnetic plate 26 is movable in the vertical direction relative to screen tensioning machine base 21. The suction force acting on the screen 24 by the magnetic plate 26 can be gauged by sagging degree of the screen 26. Therefore, the screen tensioning method further comprises the following steps.

A step 33 of detecting the sagging degree of the screen 24 by use of the sagging degree detection module.

A step 34 of adjusting the distance between the magnetic plate 26 and the screen tensioning machine base 21 in the vertical direction according to the sagging degree of the screen 24 detected by the sagging degree detection module. In practical, the step comprises that the comparing unit 281 in the magnetic plate position adjustment module 28 compares the sagging degree of the screen 24 detected by the sagging degree detection module with the preset sagging degree and generates a comparison result; that the executing unit 282 in the magnetic plate position adjustment module 28 acquires the comparison result and adjusts the distance between the magnetic plate 26 and the screen tensioning machine base 21 in the vertical direction according to the comparison result. For example, the executing unit 282 moves the magnetic plate 26 towards the screen 24 when the sagging degree detected by the sagging degree detection module 27 is greater than the preset sagging degree, moves the magnetic plate 26 away from the screen 24 when the sagging degree detected by the sagging degree detection module 27 is less than the preset sagging degree, and fixes the position of the magnetic plate 26 when the sagging degree detected by the sagging degree detection module 27 is equal to the preset sagging degree. In fact, adjusting the distance between the magnetic plate 26 and the screen tensioning machine base 21 in the vertical direction aims to adjust the distance between the magnetic plate 26 and screen 24 in the vertical direction so as to adjust the suction force applied on the screen 24 in the vertical direction by the magnetic field generated by the magnetic plate 26.

A step 35 of clamping the edge of the screen 24 by the jig 25 in the screen tensioning device 20 and tensioning the screen 24 by use of the jig 25 so that the pattern on the screen 24 is aligned with the pattern on the aligned substrate 23.

A step 36 of combining the aligned screen 24 and the screen frame 22 so as to form a mask plate as required.

In can be seen from the above that compared with the screen tensioning method of the conventional art, the screen tensioning method used during fabrication of mask plate according to the embodiment of the present disclosure is additionally provided with a step of providing a magnetic plate so as to provide an upwardly-directed vertical force to the screen and simulate a magnetic field environment in the vacuum evaporation chamber. That is to say, in the present disclosure, the mask plate is fabricated in a magnetic field environment which is similar to the magnetic field environment in the vacuum evaporation chamber. In this case, the mask plate is applied with consistent forces in the vertical direction during fabrication and during use, i.e., the mask plate is subjected to its own gravity which is downwardly directed and a suction force by the magnetic field which is upwardly directed, which makes the position of the pattern (referred to the pattern on the screen of the mask plate) during fabrication of the mask plate is the same as the position of the pattern during use of the mask plate, thereby facilitating the alignment of the pattern on the screen of the mask plate with a region of the substrate to be evaporated where a pattern needs to be deposited. Therefore, compared with the conventional art, when using mask plate fabricated by the screen tensioning device according to the embodiment of the present disclosure, the positional accuracy of the pattern formed by evaporating the organic materials onto the substrate to be evaporated can be improved.

Each of the embodiments in the present disclosure is described in a progressive manner. The same and similar portions of the various embodiments can be cross-referenced. Each embodiment is illustrated with a focus on the differences from other embodiments. In particular, for the embodiment of the screen tensioning method, since it is substantially similar to the embodiment of the screen tensioning device, the description thereof is relatively simple and the relevant portions described in the embodiment of the screen tensioning device can be referred to.

The foregoing are merely exemplary embodiments of the disclosure, but are not used to limit the protection scope of the disclosure. The protection scope of the disclosure shall be defined by the attached claims.

The present disclosure claims priority of Chinese Patent Application No. 201510250442.6 filed on May 15, 2015, the disclosure of which is hereby entirely incorporated by reference as a part of the present disclosure.

1. A screen tensioning device used during fabrication of mask plate, comprising a screen tensioning machine base and a jig provided on the screen tensioning machine base, the screen tensioning device further comprising a magnetic plate positioned above the screen tensioning machine base, and an upwardly-directed vertical suction force acting on the screen of the mask plate to be fabricated by the magnetic plate is equal to an upwardly-directed vertical suction force acting on the screen of the mask plate by a magnetic field system in a vacuum evaporation chamber during masking process.

2. The screen tensioning device used during fabrication of mask plate according to claim 1, wherein the magnetic plate is movable in the vertical direction relative to the screen tensioning machine base.

3. The screen tensioning device used during fabrication of mask plate according to claim 1, further comprising:
a sagging degree detection module configured to detect a sagging degree of the screen;
a magnetic plate position adjustment module, connected with the sagging degree detection module and the magnetic plate, respectively, wherein the magnetic plate position adjustment module adjusts a distance between the magnetic plate and the screen tensioning machine base in the vertical direction according to the sagging degree of the screen detected by the sagging degree detection module.

4. The screen tensioning device used during fabrication of mask plate according to claim 3, wherein the magnetic plate position adjustment module comprises:
a comparing unit configured to be connected with the sagging degree detection module, compare the sagging degree of the screen detected by the sagging degree detection module with a preset sagging degree and generate a comparison result; and
an executing unit connected with the comparing unit and the magnetic plate and configured to acquire the comparison result and adjust the distance between the magnetic plate and the screen tensioning machine base in the vertical direction according to the comparison result.

5. The screen tensioning device used during fabrication of mask plate according to claim 1, wherein the magnetic plate has the same size as the screen.

6. A screen tensioning method used during fabrication of mask plate, which is applicable to the screen tensioning device according to claim 1, the screen tensioning method comprising:
placing and fixing the screen frame and an aligned substrate onto the screen tensioning machine base;
disposing the screen on the screen frame and positioning the screen under the magnetic plate, wherein the magnetic plate generates an upwardly-directed vertical suction force on the screen, and the upwardly-directed vertical suction force acting on the screen by the magnetic plate is equal to the upwardly-directed vertical suction force acting on the screen by a magnetic field system in a vacuum evaporation chamber during evaporation;
clamping an edge of the screen by the jig in the screen tensioning device and tensioning the screen by use of the jig so that the pattern on the screen is aligned with the pattern on the aligned substrate; and
combining the aligned screen and the screen frame so as to form a mask plate as required.

7. The screen tensioning method used during fabrication of mask plate according to claim 6, wherein the magnetic plate is movable in the vertical direction relative to the screen tensioning machine base.

8. The screen tensioning method used during fabrication of mask plate according to claim 6, wherein the screen tensioning method further comprises:
detecting the sagging degree of the screen by the sagging degree detection module;
adjusting a distance between the magnetic plate and the screen tensioning machine base in the vertical direction according to the sagging degree of the screen detected by the sagging degree detection module.

9. The screen tensioning method used during fabrication of mask plate according to claim 8, adjusting the distance between the magnetic plate and the screen tensioning machine base in the vertical direction according to the sagging degree of the screen detected by the sagging degree detection module comprises:
the comparing unit in the magnetic plate position adjustment module compares the sagging degree of the screen detected by the sagging degree detection module with a preset sagging degree, and generates a comparison result;
the executing unit in the magnetic plate position adjustment module acquires the comparison result and adjusts the distance between the magnetic plate and the screen tensioning machine base in the vertical direction according to the comparison result.

10. The screen tensioning method used during fabrication of mask plate according to claim 6, wherein the magnetic plate has the same size as the screen.

11. The screen tensioning device used during fabrication of mask plate according to claim 2, further comprising:
a sagging degree detection module configured to detect a sagging degree of the screen;
a magnetic plate position adjustment module, connected with the sagging degree detection module and the magnetic plate, respectively, wherein the magnetic plate position adjustment module adjusts a distance between the magnetic plate and the screen tensioning machine base in the vertical direction according to the sagging degree of the screen detected by the sagging degree detection module.

12. The screen tensioning device used during fabrication of mask plate according to claim 2, wherein the magnetic plate has the same size as the screen.

13. The screen tensioning device used during fabrication of mask plate according to claim 3, wherein the magnetic plate has the same size as the screen.

14. The screen tensioning device used during fabrication of mask plate according to claim 4, wherein the magnetic plate has the same size as the screen.

15. A screen tensioning method used during fabrication of mask plate, which is applicable to the screen tensioning device according to claim 2, the screen tensioning method comprising:
placing and fixing the screen frame and an aligned substrate onto the screen tensioning machine base;
disposing the screen on the screen frame and positioning the screen under the magnetic plate, wherein the magnetic plate generates an upwardly-directed vertical suction force on the screen, and the upwardly-directed vertical suction force acting on the screen by the magnetic plate is equal to the upwardly-directed vertical suction force acting on the screen by a magnetic field system in a vacuum evaporation chamber during evaporation;
clamping an edge of the screen by the jig in the screen tensioning device and tensioning the screen by use of the jig so that the pattern on the screen is aligned with the pattern on the aligned substrate; and
combining the aligned screen and the screen frame so as to form a mask plate as required.

16. A screen tensioning method used during fabrication of mask plate, which is applicable to the screen tensioning device according to claim 3, the screen tensioning method comprising:
placing and fixing the screen frame and an aligned substrate onto the screen tensioning machine base;
disposing the screen on the screen frame and positioning the screen under the magnetic plate, wherein the magnetic plate generates an upwardly-directed vertical suction force on the screen, and the upwardly-directed vertical suction force acting on the screen by the magnetic plate is equal to the upwardly-directed vertical suction force acting on the screen by a magnetic field system in a vacuum evaporation chamber during evaporation;
clamping an edge of the screen by the jig in the screen tensioning device and tensioning the screen by use of the jig so that the pattern on the screen is aligned with the pattern on the aligned substrate; and
combining the aligned screen and the screen frame so as to form a mask plate as required.

17. The screen tensioning method used during fabrication of mask plate according to claim 7, wherein the screen tensioning method further comprises:
detecting the sagging degree of the screen by the sagging degree detection module;
adjusting a distance between the magnetic plate and the screen tensioning machine base in the vertical direction according to the sagging degree of the screen detected by the sagging degree detection module.

18. The screen tensioning method used during fabrication of mask plate according to claim 15, wherein the screen tensioning method further comprises:
detecting the sagging degree of the screen by the sagging degree detection module;
adjusting a distance between the magnetic plate and the screen tensioning machine base in the vertical direction according to the sagging degree of the screen detected by the sagging degree detection module.

19. The screen tensioning method used during fabrication of mask plate according to claim 16, wherein the screen tensioning method further comprises:
detecting the sagging degree of the screen by the sagging degree detection module;
adjusting a distance between the magnetic plate and the screen tensioning machine base in the vertical direction according to the sagging degree of the screen detected by the sagging degree detection module.

20. The screen tensioning method used during fabrication of mask plate according to claim 7, wherein the magnetic plate has the same size as the screen.
